(19) United States
(12) Patent Application Publication
(10) Pub. No.: US 2024/0061974 A1
(43) Pub. Date: Feb. 22, 2024

(54) MANAGEMENT METHOD, SYSTEM, AND PROGRAM FOR OBJECT HANDLING WORK IN DISTRIBUTION CENTER

(71) Applicant: TOYOTA JIDOSHA KABUSHIKI KAISHA, Toyota-shi (JP)

(72) Inventors: Nobuhisa OTSUKI, Tokyo-to (JP); Tomoyuki KAGA, Mishima-shi (JP); Hiroya MATSUBAYASHI, Tokyo-to (JP); Yuki ICHIOKA, Kawasaki-shi (JP); Takumi BAN, Tokyo-to (JP); Hideo HASEGAWA, Nagoya-shi (JP)

(73) Assignee: TOYOTA JIDOSHA KABUSHIKI KAISHA, Toyota-shi (JP)

(21) Appl. No.: 18/352,352

(22) Filed: Jul. 14, 2023

(30) Foreign Application Priority Data
Aug. 22, 2022 (JP) 2022-131878

(51) Int. Cl. G06F 30/20

(52) U.S. Cl. CPC G06F 30/20

(57) ABSTRACT

The method of the present disclosure comprises the following first to fourth steps. The first step is a step of calculating, by simulation, a model time requited for each action of object handling work for an object handled in a distribution center. The second step is a step of determining a start time and an end time of each action based on an analysis of camera image data obtained in the distribution center. The third step is a step of calculating an actual time required for each action from a time difference between the start time and the end time of each action. The fourth step is a step of calculating a difference between the actual time required and the model time required for each action.

### CROSS-REFERENCE TO RELATED APPLICATION

The present application claims priority under 35 U.S.C. § 119 to Japanese Patent Application No. 2022-131878, filed Aug. 22, 2022, the contents of which application are incorporated herein by reference in their entirety.

### BACKGROUND

### Field

The present disclosure relates to a management method, a management system, and a management program for object handling work in a distribution center.

### Background Art

JP2007-041950A discloses a system for performing simulation for production line management. This system compares the simulation results with actual result data of an actual production line and displays the comparison results. When the compared value becomes worse than the preset value or the overall average value including other simulation results, the system determines that attention is necessary and additionally registers attention information in the comparison content. The registration of the attention information makes it possible to grasp the problem of the production line.

In the prior art described in JP2007-041950A, the simulation results are assumed to be the number of inputs, the production amount, the number of products in process, the lead time, the number of workers, and the production efficiency. That is, in the prior art, these evaluation items are acquired as actual result data and are compared with simulation results. However, these evaluation items are set with a focus on the entire process of the production line, and do not focus on each action of workers and robots involved in each process. Therefore, in the prior art, it is not possible to evaluate whether or not the time required for each action is delayed with respect to the reference time.

As documents showing the technical level of the technical field related to the present disclosure, JP2007-094981A and JP2007-133543A can be exemplified in addition to JP2007-041950A.

### SUMMARY

In a distribution center, a plurality of workers and robots perform object handling work on goods, packages, and other objects. If it can be evaluated whether or not the time required for each action of the object handling work is delayed with respect to the reference time, it becomes possible to determine which action of the object handling work has a problem when a delay occurs in the object handling work. If the problem can be determined at the action level, it is expected to examine a concrete and appropriate improvement measure for the delay.

The present disclosure has been made in view of the above problem. An object of the present disclosure is to determine which action of object handling work has a problem when a delay occurs in the object handling work performed in a distribution center.

The present disclosure provides a management method for object handling work in a distribution center. The method of the present disclosure comprises the following first to fourth steps. The first step is a step of calculating, by simulation, a model time requited for each action of object handling work for an object handled in a distribution center. The second step is a step of determining a start time and an end time of each action based on an analysis of camera image data obtained in the distribution center. The third step is a step of calculating an actual time required for each action from a time difference between the start time and the end time of each action. The fourth step is a step of calculating a difference between the actual time required and the model time required for each action.

The present disclosure also provides a management system for object handling work in a distribution center. The system of the present disclosure comprises at least one processor and a program memory communicatively coupled to the at least one processor and storing a plurality of instructions. The plurality of instructions is configured to cause the at least one processor to execute the following first to fourth processes. The first process is a process of calculating, by simulation, a model time requited for each action of object handling work for an object handled in a distribution center. The second process is a process of determining a start time and an end time of each action based on an analysis of camera image data obtained in the distribution center. The third process is a process of calculating an actual time required for each action from a time difference between the start time and the end time of each action. The fourth process is a process of calculating a difference between the actual time required and the model time required for each action.

Further, the present disclosure provides a management program for object handling work in a distribution center. The program of the present disclosure is configured to cause at least one processor to execute the first to fourth processes described above.

According to the method, the system, and the program of the present disclosure, since the start time and the end time of each action of the object handling work are determined by analyzing the camera image data, comparison becomes possible between the calculation result of the time required for each action of the object handling work by the simulation and the actual result data. Therefore, when a delay occurs in the object handling work performed in the distribution center, it is determined which action of the object handling work has a problem.

The method of the present disclosure may further comprise the following fifth to eighth steps. The fifth step is a step of calculating, by simulation, a model time required for each element action when each action is decomposed into one or more element actions The sixth step is a step of determining a start time and an end time of each element action based on an analysis of the camera image data The seventh step is a step of calculating an actual time required for each element action from a time difference between the start time and the end time of each element action. The eighth step is a step of calculating a difference between the actual time required and the model time required for each element action.

In the system of the present disclosure, the plurality of instructions may be configured to further cause the at least one processor to execute the following fifth to eighth processes. The fifth process is a process of calculating, by simulation, a model time required for each element action when each action is decomposed into one or more element actions. The sixth process is a process of determining a start time and an end time of each element action based on an analysis of the camera image data. The seventh process is a process of calculating an actual time required for each element action from a time difference between the start time and the end time of each element action. The eighth process is a process of calculating a difference between the actual time required and the model time required for each element action.

The program of the present disclosure may be configured to further cause the at least one processor to execute the fifth to eighth processes described above. The program according to the present disclosure may be provided by being stored in a non-transitory computer-readable storage medium.

As described above, according to the method, the system, and the program of the present disclosure, when a delay occurs in the object handling work performed in the distribution center, it is possible to determine which action of the object handling work has a problem.

### BRIEF DESCRIPTION OF THE DRAWINGS

FIG. 1 is a diagram illustrating an overview of a management system according to an embodiment of the present disclosure.

FIG. 2 is a diagram for explaining an example of actions of work subjects defined in Digital Twin obtained by reproducing an actual distribution center in a digital space.

FIG. 3 is a diagram showing an example of a flow of object handling work in the distribution center.

FIG. 4 is a diagram showing an example of a flow of an action of the object handling work in the distribution center.

FIG. 5 is a flowchart showing a method for evaluating actions of work subjects using actual times required and model times required.

FIG. 6 is a flowchart showing a method for evaluating element actions of a work subject using actual times required and model times required.

### DETAILED DESCRIPTION

Hereinafter, a management method and a management system according to an embodiment of the present disclosure will be described with reference to the drawings. The management method according to the embodiment is achieved by computer processing performed in the management system according to the embodiment. In the drawings, the same or corresponding parts are denoted by the same reference numerals, and the description thereof will be simplified or omitted.

### 1. Outline of Management System

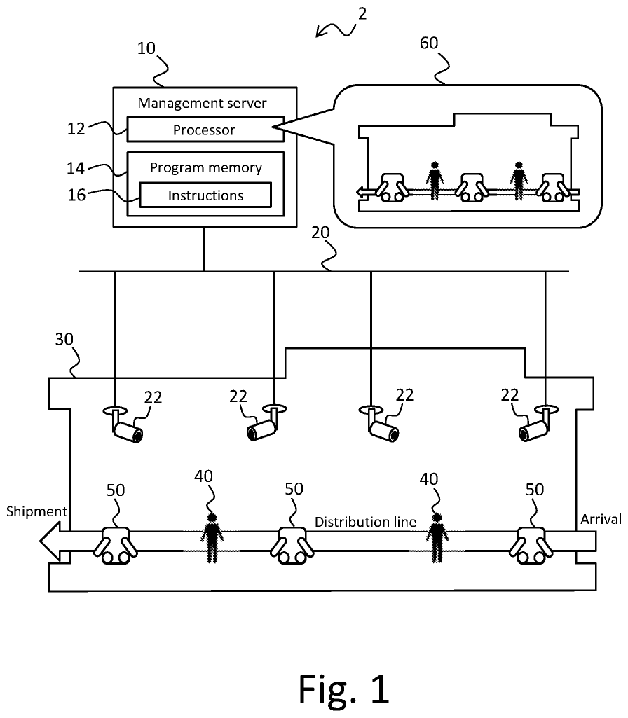

The management system according to the present embodiment is a management system that manages object handling work in a distribution center. FIG. 1 is a diagram showing an outline of a management system 2 according to the present embodiment.

The management system 2 includes a management server 10. Management of object handling work in the distribution center 30 is performed by the management server 10. The management server 10 itself can be regarded as the management system 2. In the example illustrated in FIG. 1, one management server 10 is provided for one distribution center 30. However, a plurality of management servers may be provided for one distribution center, or one management server may be provided for a plurality of distribution center.

In the distribution center 30, a plurality of workers 40 and a plurality of robots 50 work. The workers 40 and the robots 50 are lined up on a physical distribution line from arrival to shipment in order to handle objects (for example, packages and goods) handled in the distribution center 30. Alternatively, the workers 40 and the robots 50 constitute a distribution line. In the present specification, the operator 40 and the robot 50 in charge of the object handling work may be collectively referred to as a work subject.

A plurality of monitoring cameras 22 are installed in the distribution center 30. The monitoring cameras 22 may be stationary, mounted on a wall or a ceiling, or mobile, mounted on a robot or a vehicle. Some of the monitoring cameras 22 are arranged at places where actions of the worker 40 with respect to the object can be captured, in particular, at places where the hands of the worker 40 can be viewed. In addition, when the robot is in charge of a part of the object handling work, some other of the monitoring cameras 22 are arranged at places where the actions of the robot 50 with respect to the object can be captured. In the distribution center 30, the monitoring cameras 22 are distributed so as to be able to capture the actions of all work subjects responsible for the object handling work. Image data captured by the monitoring cameras 22 is transmitted to the management server 10 via network 20.

The management server 10 is configured by one or more computers provided in a cloud. The management server 10 includes at least one processor (hereinafter simply referred to as a processor) 12 and a program memory 14 communicatively coupled to the processor 12. The program memory 14 stores a plurality of instructions 16 executable by the processor 12.

The plurality of instructions 16 include instructions for causing the management server 10 to function as an image data analyzer that analyzes camera image data transmitted from the monitoring cameras 22. The plurality of instructions 16 include instructions for causing the management server 10 to function as a simulator. When the management server 10 functions as the simulator, the management server 10 constructs Digital Twin 60 in which the distribution center is reproduced in the digital space. Furthermore, the plurality of instructions 16 include instructions for causing the management server 10 to function as an evaluation device that evaluates the actions of the work subject in charge of the object handling work in the distribution center 30.

### 2. Digital Twin

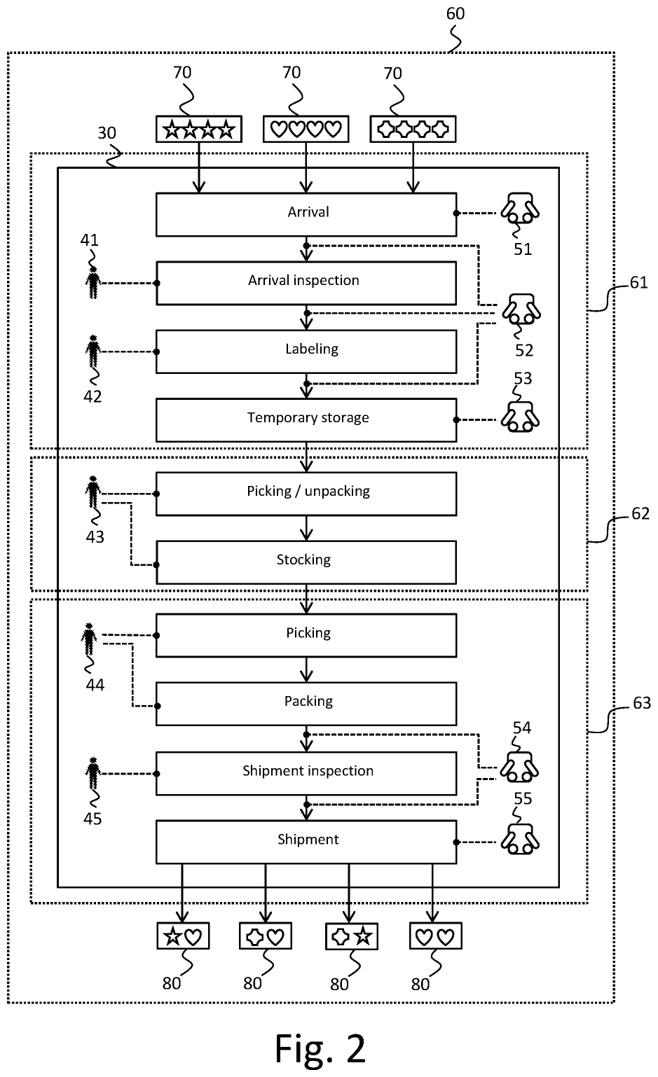

In the Digital Twin 60, an ideal state of the actual distribution center 30 is reproduced. In the actual distribution center 30, object handling work for an object handled in the distribution center is performed by cooperation of a plurality of work subjects. In other words, a series of object handling work is configured by cooperation of each action of the plurality of work subjects. FIG. 2 illustrates an example of actions of the work subjects performed in the distribution center 30. “Arrival”, “arrival inspection”, “labeling”, “temporary storage”, “picking/unpacking”, “stocking”, “picking”, “packing”, “shipment inspection”, and “shipment” shown in FIG. 2 are defined in the Digital Twin 60 as the actions of the work subjects.

The distribution center 30 illustrated in FIG. 2 is a stock-type distribution center in which transport boxes 70 for a plurality of types of goods are temporarily stored, and delivery boxes 80 in which the goods are combined and packed in response to an order from a customer are shipped. Therefore, examples of the object handling work performed in the distribution center 30 include object handling work including “arrival”, “arrival inspection”, “labeling”, and “temporary storage”, object handling work including “picking/unpacking” and “stocking”, and object handling work including “picking”, “packing”, “shipment inspection”, and “shipment”. However, the management method and the management system according to the present disclosure are also applied to a pass-through distribution center that mainly delivers packages.

In the example shown in FIG. 2, the robot 51 takes charge of “arrival” of the transport box 70, and the worker 41 takes charge of “arrival inspection” of the transport box 70. “Labeling” of the transport box 70 is performed by the worker 42, and “temporary storage” of the transport box 70 is performed by the robot 53. The robot 52 takes charge of the transportation of the transport box 70 from “arrival” to “temporary storage”. The Digital Twin 60 is composed of three sets of Digital Twin 61, 62, and 63. The Digital Twin 61 reproduces an ideal state of the real space in which the object handling work from “arrival” to “temporary storage” is performed. Therefore, each action defined by the Digital Twin 61 is also an action in an ideal state. By the simulation using the Digital Twin 61, the model time required for each action from “arrival” to “temporary storage” is calculated.

In the example illustrated in FIG. 2, the worker 43 takes charge of “picking/unpacking” of the transport box 70 and “stocking” of goods taken out from the transport box. The Digital Twin 62 reproduces an ideal state of the real space in which the object handling work from “picking/unpacking” to “stocking” is performed. By the simulation using the Digital Twin 62, the model time required for each action from “picking/unpacking” to “stocking” is calculated.

In the example illustrated in FIG. 2, the worker 44 takes charge of “picking” goods from a shelf and “packing” the picked goods in the delivery box 80. The worker 45 takes charge of “shipment inspection” of the delivery box 80 in which the goods are packed, and the robot 55 takes charge of “shipment” of the delivery box 80. Then, the robot 54 takes charge of the transportation of the delivery box 80 from “packing” to “shipment”. The Digital Twin 63 reproduces an ideal state of the real space in which the object handling work from “picking” to “shipment” is performed. The model time required for each action from “picking” to “shipment” is calculated by the simulation using the Digital Twin 63.

Further, in the simulation using each of the Digital Twin 61, 62, and 63, the model time required for each element action when each action from “arrival” to “shipment” is decomposed into one or more element actions is calculated. As a specific example, the action of “labeling” by the worker 42 is decomposed into an action of operating a label issuing machine to issue a label, an action of approaching the transport box 70 while holding the label, and an action of attaching the label to the transport box 70. Each of these element actions has an ideal action, and the time required for the ideal action is calculated as the model time required for the element action.

Although not included in the object handling work shown in FIG. 2, one example of the action is “measuring package”. The element actions of “measuring package” may include “moving”, “holding”, “placing”, “pushing”, and “waiting”. Another example of the action is “moving to a place with a package”. Examples of element actions of “moving to a place with a package” include “holding a package”, “moving to a measuring machine”, “placing a package”, “pressing a measurement button”, “waiting”, “holding a package”, “moving to a storage area”, and “placing a package”.

### 3. Camera Image Data Analysis

The management server 10 calculates the actual time required for each action of work subjects in charge of the object handling work in the distribution center 30. The camera image data transmitted from the monitoring camera 22 is used to calculate the actual time required for each action of work subjects. The management server 10 as an image data analyzer determines a start time and an end time of each action of work subjects from camera image data.

The state regarded as the start of the action and the state regarded as the end of the action are predefined for each action. Regarding the start of the action, for example, the touch of the hand with the package may be defined as the start of the action, or the press of a button may be defined as the start of the action. With regard to the end of the action, for example, separation of the hand from the package may be defined as the end of the action, or return of the work subject to a predetermined position may be defined as the end of the action.

The management server 10 marks the camera image data obtained by capturing the state regarded as the start of the action, and records the time code included in the marked camera image data as the start time of the action. Further, the management server 10 marks the camera image data obtained by capturing the state regarded as the end of the action, and records the time code included in the marked camera image data as the end time of the action.

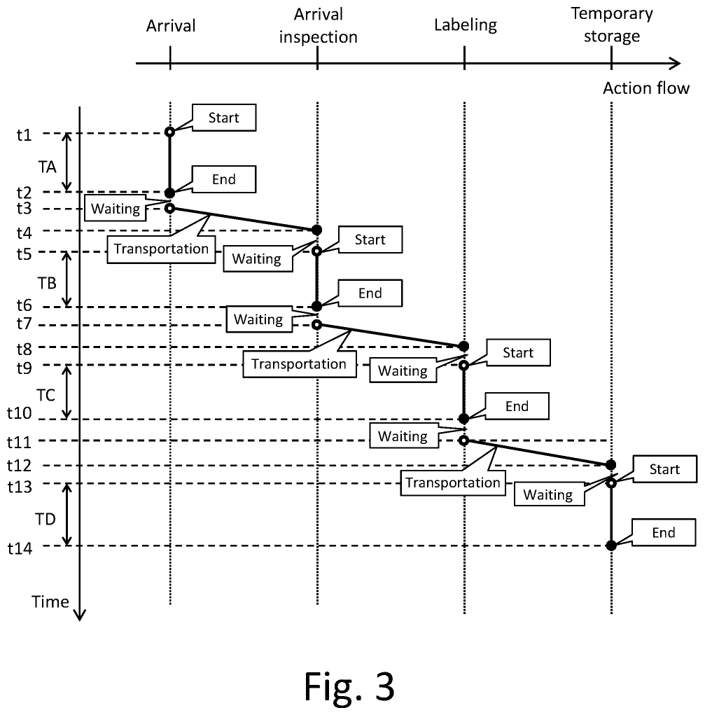

FIG. 3 is a diagram illustrating an example of a flow of object handling work in the distribution center 30. FIG. 3 shows a flow of object handling work including “arrival”, “arrival inspection”, “labeling”, and “temporary storage”. As simulated in the Digital Twin 61 shown in FIG. 2, “arrival” is an action by the robot 51, “arrival inspection” is an action by the worker 41, “labeling” is an action by the worker 42, and “temporary storage” is an action by the robot 53.

In the example shown in FIG. 3, the time t1 is acquired as the start time of “arrival” and the time t2 is acquired as the end time of “arrival”. Next, the time t5 is acquired as the start time of the “arrival inspection”, and the time t6 is acquired as the end time of the “arrival inspection”. Further, the time t9 is acquired as the start time of “labeling”, and the time t10 is acquired as the end time of “labeling”. Finally, the time t13 is acquired as the start time of the “temporary storage”, and the time t14 is acquired as the end time of the “temporary storage”.

The management server 10 calculates the time difference TA between the time t1 and the time t2 as the actual time required for the arrival action by the robot 51, and calculates the time difference TB between the time t5 and the time t6 as the actual time required for the arrival inspection action by the worker 41. In addition, management server 10 calculates time difference TC between time t9 and time t10 as the actual time required for the labeling action by worker 42, and calculates time difference TD between time t13 and time t14 as the actual time required for the temporary storage action by robot 53.

The time of the object handling work includes the transporting time of the transport box 70 by the robot 52. The transportation of the transport box 70 from “arrival” to “arrival inspection” is performed between time t3 and time t4. Further, the transportation of the transport box 70 from “arrival inspection” to “labeling” is performed between time t7 and time t8. The transportation of the transport box 70 from “labeling” to “temporary storage” is performed between time t11 and time t12.

Depending on the relationship between the processing speeds of the work subjects and the arrival timing of the transport box 70 to be received, a waiting time is generated before and after the action. The time from the time t2 to the time t3, the time from the time t6 to the time t7, and the time from the time t10 to the time t11 correspond to the waiting time from the end of the immediately previous action to the transportation of the transport box 70. The time from the time t4 to the time t5, the time from the time t8 to the time t9, and the time from the time t12 to the time t13 correspond to the waiting time until the start of the next action after transportation of the transport box 70. These waiting times tend to increase as the difference between the actual time required and the model time required for each action increases.

The management server 10 determines the start time and the end time of each action of the object handling work from “picking/unpacking” to “stocking”, and calculates the actual time required based on the time difference between the start time and the end time for each action. In addition, the management server 10 determines the start time and the end time of each action of the object handling work from “picking” to “shipment” and calculates the actual time required based on the time difference between the start time and the end time for each action.

Further, the management server 10 also calculates the actual time required of each element action of each work subject. As defined in the Digital Twin 60, each of “arrival”, “arrival inspection”, “labeling”, “temporary storage”, “picking/unpacking”, “stocking”, “picking”, “packing”, “shipment inspection”, and “shipment” includes one or more element actions. In order to calculate the actual time required for each element action, the management server 10 determines the start time and the end time of each element action based on the analysis of the camera image data. The element whose actual time required is calculated based on the analysis of the camera image data corresponds to the element action whose model time required is calculated by the simulation using the Digital Twin 60.

The state regarded as the start of the element action and the state regarded as the end of the element action are defined in advance for each element action. For example, a particular state within an action is defined as the start or end of an element action. Further, since a plurality of element actions are connected to form one action, the end of the previous element action is the start of the next element action. The management server 10 marks the camera image data obtained by capturing the state regarded as the start of the element action, and records the time code included in the marked camera image data as the start time of the element action. Further, the management server 10 marks the camera image data obtained by capturing the state regarded as the end of the element action, and records the time code included in the marked camera image data as the end time of the element action.

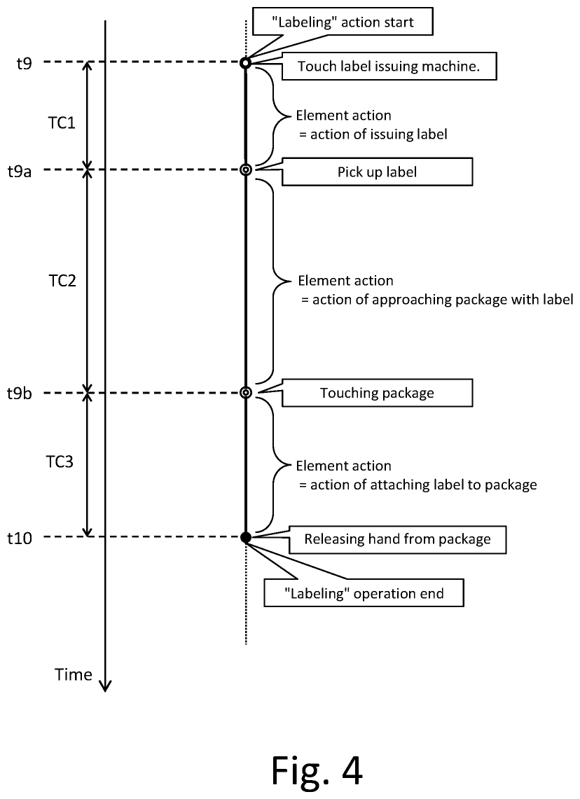

FIG. 4 is a diagram illustrating an example of a flow of an action of the object handling work in the distribution center 30. FIG. 4 shows the flow of the “labeling” action. As simulated in the Digital Twin 61 shown in FIG. 2, “labeling” is an action by the worker 42, and labeling for one transport box 70 is consistently performed by the worker 42. “Labeling” by the worker 42 includes three element actions of an “action of issuing a label”, an “action of approaching a package with a label”, and an “action of attaching a label to a package”. The management server 10 determines the start time and the end time of each element action based on the analysis of the camera image data.

In the example shown in FIG. 4, the touch of the worker 42 with the label issuing machine at time t9 is detected as the start time of the “action of issuing a label”. Next, the fact that the worker 42 picks up the label at the time t9a is detected as the end time of the “action of issuing a label” and is also detected as the start time of the “action of approaching a package with a label”. Further, the fact that the worker 42 touches the package at the time t9b is detected as the end time of the “action of approaching a package with a label” and is detected as the start time of the “action of attaching a label to a package”. Finally, the fact that the worker 42 releases his/her hand from the package at the time t10 is detected as the end time of the “action of attaching a label to the package”.

The management server 10 calculates the time difference TC1 between the time t9 and the time t9a as the actual time required for the element action in which the worker 42 issues the label. In addition, the management server 10 calculates the time difference TC2 between the time t9a and the time t9b as the actual time required for the element action in which the worker 42 approaches the package with the label. Furthermore, management server 10 calculates a time difference TC3 between time t9b and time t10 as the actual time required for the element action in which the worker 42 attaches the label to the package.

### 4. Evaluation of Action

The management server 10 as an evaluation device evaluates the actions of all the work subjects in charge of the object handling work in the distribution center 30. As information for the evaluation, the management server 10 uses the model time required for each action calculated by the simulation using the Digital Twin 60 and the actual time required for each action obtained by analyzing the camera image data.

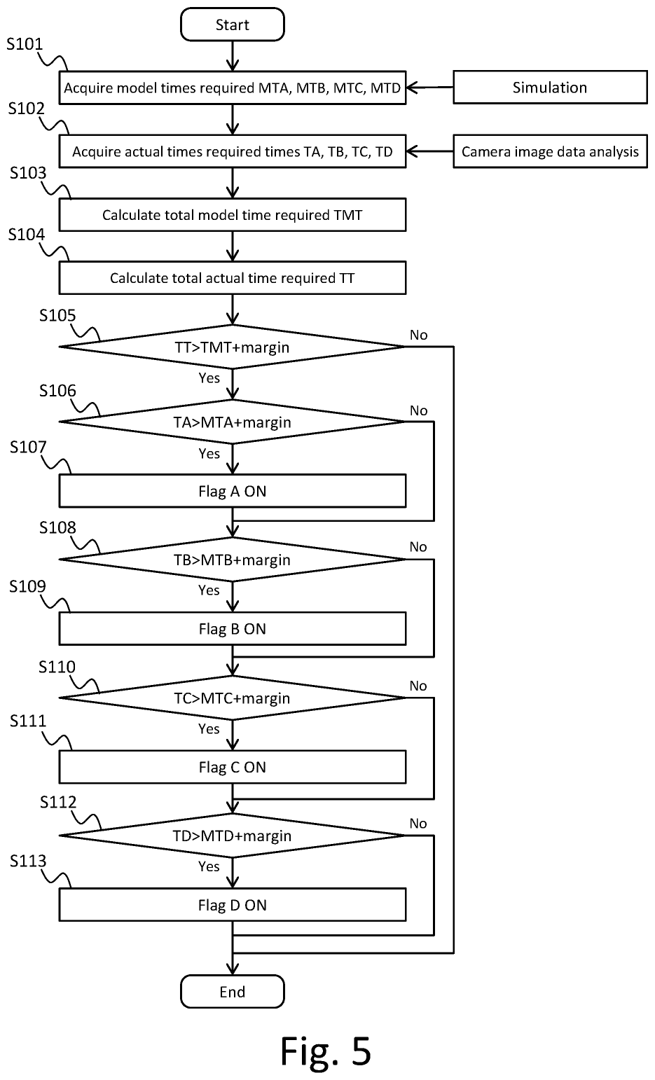

FIG. 5 is a flowchart showing a method of evaluating actions of work subjects using the actual times required and the model times required. The method of evaluating actions of work subjects is to first evaluate whether or not there is a problem in a series of object handling work and, if there is a problem, to evaluate each action included in the object handling work. FIG. 5 illustrates an evaluation flow for evaluating actions included in a series of object handling work from “arrival” to “temporary storage” among the object handling work in the distribution center 30.

First, in step S101, the model times required MTA, MTB, MTC, and MTD for respective actions calculated by simulation using the Digital Twin 61 are acquired. The model time required MTA is the model time required for the arrival action, the model time required MTB is the model time required for the arrival inspection action, the model time required MTC is the model time required for the labeling action, and the model time required MTD is the model time required for the temporary storage action. In Step S102, the actual times required TA, TB, TC, and TD for respective actions are acquired.

In step S103, the sum of the model times required MTA, MTB, MTC, and MTD acquired in step S101 is calculated as the total model time required TMT. In step S104, the sum of the actual times required TA, TB, TC, and TD acquired in step S102 is calculated as the total actual time required TT.

Next, in step S105, the total model time required TMT and the total actual time required TT are compared. Specifically, it is determined whether or not the total actual time required TT is larger than a value obtained by adding a predetermined margin to the total model time required TMT. If the determination result is negative, the evaluation flow ends.

The difference between the total model time required TMT and the total actual time required TT represents the delay of the actual object handling work relative to the ideal. The margin included in the comparison equation of step S105 is the allowable delay time. Therefore, if the determination result of step S105 is positive, it means that an unacceptable delay occurs in the series of object handling work from “arrival” to “temporary storage”.

If the result of the determination in step S105 is positive, it is determined which of the actions included in the object handling work has a problem. The processes from step S106 to step S113 are processes for determining the presence or absence of a problem for each action.

In step S106, the model time required MTA and the actual time required TA for the arrival action are compared. Specifically, it is determined whether or not the actual time required TA is larger than a value obtained by adding a predetermined margin to the model time required MTA. The margin in the comparison equation of step S106 is the allowable delay time in the arrival action. If the determination result is positive, the flag A is turned on in step S107. The flag A is a flag indicating that there is a problem in the arrival action. If the determination result is negative, step S107 is skipped.

In Step S108, the model time required MTB and the actual time required TB for the arrival inspection action are compared. Specifically, it is determined whether or not the actual time required TB is larger than a value obtained by adding a predetermined margin to the model time required MTB. The margin in the comparison equation of step S108 is the allowable delay time in the arrival inspection action. If the determination result is positive, the flag B is turned on in step S109. The flag B is a flag indicating that there is a problem in the arrival inspection action. If the determination result is negative, step S109 is skipped.

In step S110, the model time required MTC and the actual time required TC for the labeling action are compared. Specifically, it is determined whether or not the actual time required TC is larger than a value obtained by adding a predetermined margin to the model time required MTC. The margin in the comparison equation of step S110 is the allowable delay time in the labeling action. If the determination result is positive, the flag C is turned on in step S111. The flag C is a flag indicating that there is a problem in the labeling action. If the determination result is negative, step S111 is skipped.

In step S112, the model time required MTD and the actual time required TD for the temporary storage action are compared. Specifically, it is determined whether or not the actual time required TD is larger than a value obtained by adding a predetermined margin to the model time required MTD. The margin in the comparison equation of step S112 is the allowable delay time in the temporary storage action. If the determination result is positive, the flag D is turned on in step S113. The flag D is a flag indicating that a problem occurs in the temporary storage action. After the execution of step S113, the evaluation flow ends. If the determination result of step S112 is negative, step S113 is skipped and the evaluation flow ends.

By executing the above-described evaluation flow, it is possible to determine which work subject causes a delay in the object handling work. The evaluation flow shown in FIG. 5 can be executed at any time after the series of object handling work from “arrival” to “temporary storage” are executed and the actual time required for each action is acquired. For example, the evaluation flow may be executed each time the series of object handling work is executed, or the evaluation flow may be executed for one day after completion of one day's work in the distribution center 30.

Further, when the action causing the delay in the object handling work is determined, the management server 10 as the evaluation device evaluates each element action of the action. As information for the evaluation, the management server 10 uses the model time required for each element action calculated by the simulation using the Digital Twin 60 and the actual time required for each element action obtained by analyzing the camera image data.

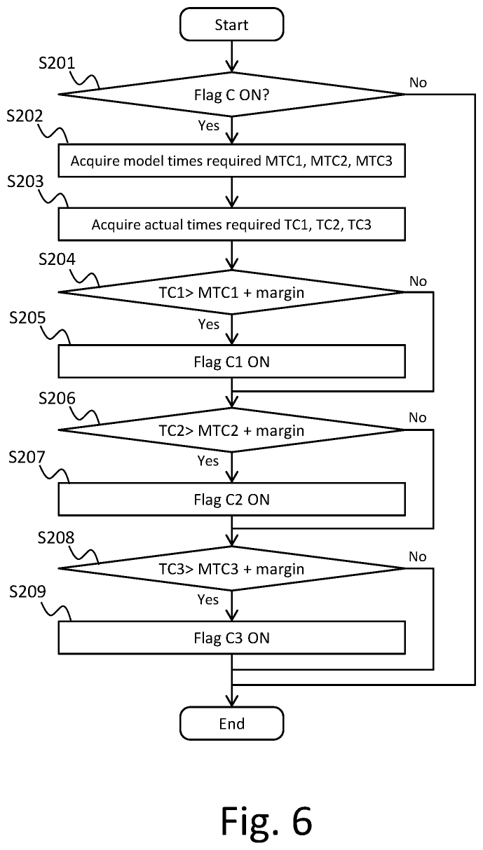

FIG. 6 is a flowchart showing a method of evaluating element actions of a work subject using actual times required and model times required. FIG. 6 shows an evaluation flow for evaluating element actions of the labeling action.

First, in step S201, it is determined whether or not the flag C is ON. If there is a problem in the labeling action, the flag C is turned on in the evaluation flow shown in FIG. 5. If the flag C is off, there is no problem in the labeling action. In this case, the evaluation flow ends.

If the result of the determination in step S201 is positive, it is determined which of the elementary actions constituting the labeling action has a problem. The processes from step S202 to step S209 are processes for determining the presence or absence of a problem with respect to each element action.

In step S202, the model times required MTC1, MTC2, and MTC3 for respective element actions constituting the labeling action calculated by the simulation using the Digital Twin 61 are acquired. The model time required MTC1 is the model time required for the action of issuing a label, the model time required MTC2 is a model time required for the action of approaching a package with the label, and the model time required MTC3 is a model time required for the action of attaching the label to the package. In step S203, actual times required TC1, TC2, and TC3 for respective element actions are obtained by analyzing the camera image data.

In step S204, the model time required MTC1 and the actual time required TC1 for the label issuing action are compared. Specifically, it is determined whether or not the actual time required TC1 is larger than a value obtained by adding a predetermined margin to the model time required MTC1. The margin in the comparison equation of step S204 is the allowable delay time in the label issuing action. If the determination result is positive, the flag C1 is turned on in step S205. The flag C1 is a flag indicating that there is a in the label issuing action. If the determination result is negative, step S205 is skipped.

In step S206, the model time required MTC2 and the actual time required TC2 for the action of approaching the package with the label are compared. Specifically, it is determined whether or not the actual time required TC2 is larger than a value obtained by adding a predetermined margin to the model time required MTC2. The margin in the comparison equation of step S206 is the allowable delay time in the action of approaching the package with the label. If the determination result is positive, the flag C2 is turned on in step S207. The flag C2 is a flag indicating that there is a problem in the action of approaching the package with the label. If the determination result is negative, step S207 is skipped.

In step S208, the model time required MTC3 and the actual time required TC3 for the action of attaching the label to the package are compared. Specifically, it is determined whether or not the actual time required TC3 is larger than a value obtained by adding a predetermined margin to the model time required MTC3. The margin in the comparison equation of step S208 is the allowable delay time in the action of attaching the label to the package. If the determination result is positive, the flag C3 is turned on in step S209. The flag C3 is a flag indicating that there is a problem in the action of attaching the label to the package. If the determination result is negative, step S209 is skipped. After the execution of step S209, the evaluation flow ends. If the determination result of step S208 is negative, step S209 is skipped and the evaluation flow ends.

By executing the above-described evaluation flow, when a delay occurs in the action of the work subject, it is possible to determine which element action causes the delay. The evaluation flow shown in FIG. 6 can be executed at any time after the series of object handling work from “arrival” to “temporary storage” is executed and the actual time required for each element action for each action is acquired. For example, the evaluation flow may be executed each time the series of object handling work is executed, or the evaluation flow may be executed for one day after completion of one day's work in the distribution center 30.

### 5. Effect

According to the embodiment described above, when a delay occurs in the object handling work performed in the distribution center 30, it is possible to determine which action of the object handling work has a problem. Further, it is possible to determine which element action causes the problem with respect to the action having the problem. By feeding back the determined problem to the work subject, it is possible to improve the action of the work subject and increase the producibility of the distribution center 30.

What is claimed is:

1. A method comprising:
calculating, by simulation, a model time requited for each action of object handling work for an object handled in a distribution center;
determining a start time and an end time of the each action based on an analysis of camera image data obtained in the distribution center;
calculating an actual time required for the each action from a time difference between the start time and the end time of the each action; and
calculating a difference between the actual time required and the model time required for the each action.

2. The method according to claim 1, further comprising:
calculating, by simulation, a model time required for each element action when the each action is decomposed into one or more element actions;
determining a start time and an end time of the each element action based on an analysis of the camera image data;
calculating an actual time required for the each element action from a time difference between the start time and the end time of the each element action; and
calculating a difference between the actual time required and the model time required for the each element action.

3. A system comprising:
at least one processor; and
a program memory communicatively coupled to the at least one processor, the program memory storing a plurality of instructions configured to cause the at least one processor to execute:
calculating, by simulation, a model time requited for each action of object handling work for an object handled in a distribution center;
determining a start time and an end time of the each action based on an analysis of camera image data obtained in the distribution center;
calculating an actual time required for the each action from a time difference between the start time and the end time of the each action; and
calculating a difference between the actual time required and the model time required for the each action.

4. The system according to claim 3, wherein
the plurality of instructions is configured to further cause the at least one processor to execute:
calculating, by simulation, a model time required for each element action when the each action is decomposed into one or more element actions;
determining a start time and an end time of the each element action based on an analysis of the camera image data;
calculating an actual time required for the each element action from a time difference between the start time and the end time of the each element action; and
calculating a difference between the actual time required and the model time required for the each element action.

5. A non-transitory computer-readable storage medium storing a program comprising a plurality of instructions configured to cause at least one processor to execute:
calculating, by simulation, a model time requited for each action of object handling work for an object handled in a distribution center;
determining a start time and an end time of the each action based on an analysis of camera image data obtained in the distribution center;
calculating an actual time required for the each action from a time difference between the start time and the end time of the each action; and
calculating a difference between the actual time required and the model time required for the each action.

6. The non-transitory computer-readable storage medium according to claim 5, wherein
the plurality of instructions is configured to further cause the at least one processor to execute:
calculating, by simulation, a model time required for each element action when the each action is decomposed into one or more element actions;
determining a start time and an end time of the each element action based on an analysis of the camera image data;
calculating an actual time required for the each element action from a time difference between the start time and the end time of the each element action; and
calculating a difference between the actual time required and the model time required for the each element action.
